(19) United States
(12) Patent Application Publication
(10) Pub. No.: US 2026/0189214 A1
(43) Pub. Date: Jul. 2, 2026

(54) BIDIRECTIONAL VARIABLE GAIN PHASE SHIFTER BASED ON ASYMMETRIC POWER DISTRIBUTION

(71) Applicant: UIF (University Industry Foundation), Yonsei University, Seoul (KR)

(72) Inventors: Byung-Wook MIN, Seoul (KR); Sungwon KWON, Seoul (KR)

(21) Appl. No.: 19/432,837

(22) Filed: Dec. 24, 2025

(30) Foreign Application Priority Data
Dec. 30, 2024 (KR) 10-2024-0199934

(51) Int. Cl. H03H 11/20; H03H 11/32

(52) U.S. Cl. CPC H03H 11/20; H03H 11/32

(57) ABSTRACT

A bidirectional variable gain phase shifter includes: a rat-race coupler configured to distribute an input signal at a predetermined ratio and divide the input signal into first and second distributed signals; a phase inversion switch circuit configured to selectively invert phases of the respective first and second distributed signals; a hybrid coupler configured to receive two signals output from the phase inversion switch circuit, to phase-shift and combine the received signals, and to obtain first and second phase-shifted signals; and a phase selection switch configured to select one of the first and second phase-shifted signals and output the selected signal as an output signal, wherein phase and gain can be accurately adjusted bidirectionally without attenuation, insertion loss is low, and calibration is not required.

### CROSS-REFERENCE TO RELATED APPLICATIONS

This application claims priority under 35 U.S.C. § 119 (a) to Korean Patent Application No. 10-2024-0199934, filed on Dec. 30, 2024, with the Korean Intellectual Property Office, the disclosure of which is incorporated herein in its entirety by reference.

### BACKGROUND

### 1. Technical Field

The disclosed embodiments relate to a bidirectional variable gain phase shifter, and more particularly, to a bidirectional variable gain phase shifter based on asymmetric power distribution.

### 2. Description of the Related Art

As the demand for high-speed data communication continues to increase, the importance of phased array systems is also increasing. In general, phased array systems enhance antenna directivity by utilizing phase differences between individual antennas, thereby mitigating severe path loss at millimeter-wave frequencies. Recently, Vector-Sum Phase Shifters (hereinafter referred to as “VSPS”) have been mainly used to generate phase differences between antennas.

Among VSPSs, an Active-VSPS (hereinafter referred to as “A-VSPS”) is known to have high phase resolution, high voltage gain, and wide bandwidth. However, since an A-VSPS includes Variable Gain Amplifiers (VGAs) disposed in I/Q paths, it suffers from high power consumption, low linearity, and an inability to operate bidirectionally. In addition, there is a problem in that complex voltage control is required to manage phase and gain states.

Accordingly, a Passive-VSPS (hereinafter referred to as “P-VSPS”), in which the VGA of the A-VSPS is replaced with an X-type attenuator (X-ATT) to enable bidirectional operation, has been studied. Since the P-VSPS consumes no power, exhibits high linearity, and is capable of bidirectional operation, it can be used in both transmit and receive channels (TX/RX) of phased array systems. Such transmit/receive sharing functionality makes it possible to reduce chip size and simplify array calibration and beamforming. However, a phase shifter based on a combination of attenuated I/Q signals has a limitation in that insertion loss is high.

### STATEMENT REGARDING PRIOR DISCLOSURES BY THE INVENTOR OR A JOINT INVENTOR

At least one inventor or joint inventor of the present disclosure has made related disclosures in a research paper (IEEE Microwave and Wireless Technology Letters, vol. 34, no. 11, pp. 1255-1258) on October 2024, which was included in the information disclosure statement submitted with this application.

### SUMMARY

An object of the disclosed embodiments is to provide a bidirectional variable gain phase shifter capable of accurately controlling phase and gain in both directions without attenuation.

Another object of the disclosed embodiments is to provide a bidirectional variable gain phase shifter having low insertion loss and requiring no calibration.

According to an embodiment, a bidirectional variable gain phase shifter includes: a rat-race coupler configured to distribute an input signal at a predetermined ratio and divide the input signal into first and second distributed signals; a phase inversion switch circuit configured to selectively invert phases of the respective first and second distributed signals; a hybrid coupler configured to receive two signals output from the phase inversion switch circuit, to phase-shift and combine the received signals, and to obtain first and second phase-shifted signals; and a phase selection switch configured to select one of the first and second phase-shifted signals and output the selected signal as an output signal.

The rat-race coupler may distribute the input signal into the first and second distributed signals at a ratio of cos²(θ) to sin²(θ) according to a predetermined reference phase (θ).

The rat-race coupler may be implemented as a switchable directional rat-race coupler configured to phase-shift and output the first and second distributed signals in response to a phase selection signal.

The rat-race coupler may phase-shift the first and second distributed signals by varying an electrical length of a path through which the input signal is transmitted, by means of at least one switch transistor to which the phase selection signal is applied as a gate signal.

The phase inversion switch circuit may include a first phase inversion switch configured to receive the first distributed signal and to selectively pass the first distributed signal without phase inversion or with phase inversion in response to a first switching control signal, and a second phase inversion switch configured to receive the second distributed signal and to selectively pass the second distributed signal without phase inversion or with phase inversion in response to a second switching control signal.

The first phase inversion switch may adjust a magnitude of the first distributed signal according to a voltage level of the first switching control signal, and the second phase inversion switch may adjust a magnitude of the second distributed signal according to a voltage level of the second switching control signal.

The first DPDT switch may be implemented as a DPDT (Double-Pole Double-Throw) switch.

The hybrid coupler may combine two signals output from the phase inversion switch circuit as an I signal and a Q signal to obtain the first phase-shifted signal, and may interchangeably combine the two signals as a Q signal and an I signal to obtain the second phase-shifted signal.

The phase selection switch may select one of the first and second phase-shifted signals as the output signal in response to a third switching control signal.

The phase selection switch may be implemented as an absorptive SPDT (Single-Pole Double-Throw) switch so as to achieve impedance matching with the hybrid coupler.

The bidirectional variable gain phase shifter may further include a first balun circuit configured to convert the first and second distributed signals into differential signals, respectively, and a second balun circuit configured to convert two signals output as differential signals from the phase inversion switch circuit into single-ended signals, respectively.

The bidirectional variable gain phase shifter may be provided in a communication device, and, under control of a controller included in the communication device, may be configured to set a power distribution ratio of the input signal, to determine whether to invert phases of the first and second distributed signals, and to select one of the first and second phase-shifted signals.

Accordingly, the bidirectional variable gain phase shifter according to the embodiment has low insertion loss and requires no calibration, thereby enabling accurate control of phase and gain in both directions without attenuation.

### BRIEF DESCRIPTION OF THE DRAWINGS

FIG. 1 is a diagram comparing an operation of a conventional VSPS and an operation of a bidirectional variable gain VSPS according to an embodiment of the present disclosure.

FIG. 2 illustrates a schematic configuration of a bidirectional variable gain VSPS according to an embodiment of the present disclosure.

FIG. 3 illustrates an operation of the bidirectional variable gain VSPS of the embodiment shown in FIG. 2.

FIG. 4 illustrates an example of a detailed configuration of the bidirectional variable gain VSPS of FIG. 1.

### DETAILED DESCRIPTION

Hereinafter, specific embodiments of the present disclosure will be described with reference to the drawings. The following detailed description is provided to help with comprehensive understanding of a method, a device, and/or a system described in this specification. However, this is only an example, and the present disclosure is not limited thereto.

In describing embodiments of the present disclosure, when it is determined that detailed description of well-known technologies related to the present disclosure may unnecessarily obscure the gist of embodiments, the detailed description will be omitted. Terms to be described below are terms defined in consideration of functions in the present disclosure, and may vary depending on the intention, practice, or the like of a user or operator. Therefore, the terms should be defined on the basis of the overall content of this specification. Terms used in the detailed description are only used to describe embodiments and should not be construed as limiting. Unless otherwise clearly specified, a singular expression includes the plural meaning. In this description, an expression such as “include” or “have” is intended to indicate certain features, numerals, steps, operations, elements, or some or combinations thereof, and should not be construed as excluding the presence or possibility of one or more other features, numerals, steps, operations, elements, or some or combinations thereof. Also, the terms “unit,” “device,” “module,” “block,” and the like described in this specification refer to units for processing at least one function or operation, which may be implemented by hardware, software, or a combination of hardware and software.

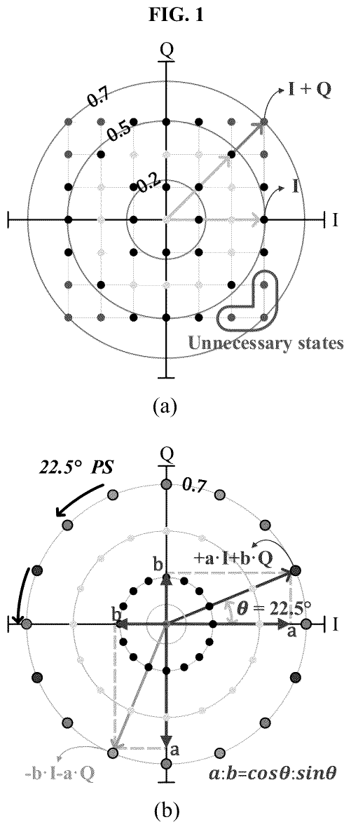

FIG. 1 is a diagram comparing an operation of a conventional VSPS and an operation of a bidirectional variable gain VSPS according to an embodiment of the present disclosure.

In FIG. 1, (a) is a diagram for explaining an operation of a conventional VSPS, and (b) is a diagram for explaining an operation of a bidirectional variable gain VSPS according to an embodiment. Both (a) and (b) in FIG. 1 illustrate S21 polar plots of a VSPS controlled with 6-bit resolution.

Referring to (a) of FIG. 1, in the case of the conventional VSPS, orthogonal I/Q (In-phase/Quadrature) signals are configured to be controlled independently. That is, magnitudes of the I signal and the Q signal divided from an input signal are independently controlled based on a predetermined number of bits. Accordingly, as illustrated in (a) of FIG. 1, the conventional VSPS outputs a signal having a phase state corresponding to a magnitude of the I signal and a magnitude of the Q signal at a designated point on an orthogonal coordinate system defined by an I-axis and a Q-axis. That is, the output signal can have only a phase state corresponding to one of a plurality of points represented in the orthogonal coordinate system.

Meanwhile, since a gain of the VSPS is represented by a sum (I+Q) of the I signal and the Q signal of the output signal, the same gain is obtained only along a circle having an identical radius in the polar plot. In (a) of FIG. 1, reference numerals 0.2, 0.5, and 0.7 indicated on three circles having gradually increasing diameters from a center of the polar plot represent gains of the VSPS.

In order for the VSPS to output an output signal having a uniform gain, phase states corresponding to each gain (0.2, 0.5, and 0.7) should be located on a circumference of a circle. However, a plurality of points defined in the orthogonal coordinate system are not located on the circumference. Accordingly, phase states are adjusted by utilizing only points among the plurality of points in the orthogonal coordinate system that are closest to the circle corresponding to each gain (0.2, 0.5, and 0.7). That is, as illustrated in (a) of FIG. 1, only points indicated in black among the plurality of points in the orthogonal coordinate system are used, while many points indicated in gray are unusable. As a result, the number of phase states that can be represented by the VSPS is significantly reduced. In this case, the number of phase states that can be output at a low gain (for example, 0.2) is further reduced. As illustrated in (a) of FIG. 1, while the VSPS can provide 16 phase states at a gain of 0.5, it can provide only 8 phase states at a gain of 0.2.

In addition, points corresponding to a high gain (here, 0.7) indicated in blue in (a) of FIG. 1 have a very small number of phase states capable of having a uniform gain, and thus become unnecessary states that cannot be used due to a lack of phase-state diversity at the corresponding gain. Accordingly, the conventional VSPS not only fails to achieve a high gain, but also has a limitation in that phase states of a signal that can be output at a low gain are extremely limited.

Furthermore, since locations of points in the orthogonal coordinate system are not positioned on circles corresponding to gains (0.2 and 0.5), additional gain adjustment must be performed in order for the phase shifter to output an output signal having a uniform gain, which results in additional attenuation.

In contrast, in the bidirectional variable gain VSPS according to an embodiment, as illustrated in (b) of FIG. 1, an output signal is configured to have a gain and a phase state corresponding to points in polar coordinates in an S21 polar plot. That is, magnitudes of the I signal and the Q signal are adjusted based on points distinguished by a radius (r) and a reference phase. Assuming, as in the conventional VSPS, a case in which control is performed with 6-bit resolution, three gains (0.2, 0.5, and 0.7) are distinguished by the radius (r), and phase states are distinguished according to a reference phase (θ) at each gain. In this case, the reference phase (θ) may be, for example, θ=π/8=22.5°.

Accordingly, the same number of phase states, i.e., 16 phase states, may be obtained at each of the three gains (0.2, 0.5, and 0.7). Since points representing phase states that the output signal may have are arranged at uniform intervals on circles corresponding to the respective gains (0.2, 0.5, and 0.7), no additional gain adjustment is required. Therefore, attenuation for additional gain adjustment does not occur. In particular, whereas the gain of 0.7 could not be utilized in (a) of FIG. 1 due to a limited number of available phase states, in (b) of FIG. 1, a uniform set of 16 phase states may be obtained even at the gain of 0.7, indicating that the VSPS according to the embodiment is capable of providing a high gain.

As described above, when the VSPS is configured to control an output signal so as to have a gain and a phase state corresponding to points in polar coordinates, not only does the number of phase states available at each gain increase, but also a higher gain (0.7) can be provided compared to the conventional approach. In addition, since the points in polar coordinates are already positioned on circumferences corresponding to the respective gains (0.2, 0.5, and 0.7), there is an advantage in that no additional gain control is required.

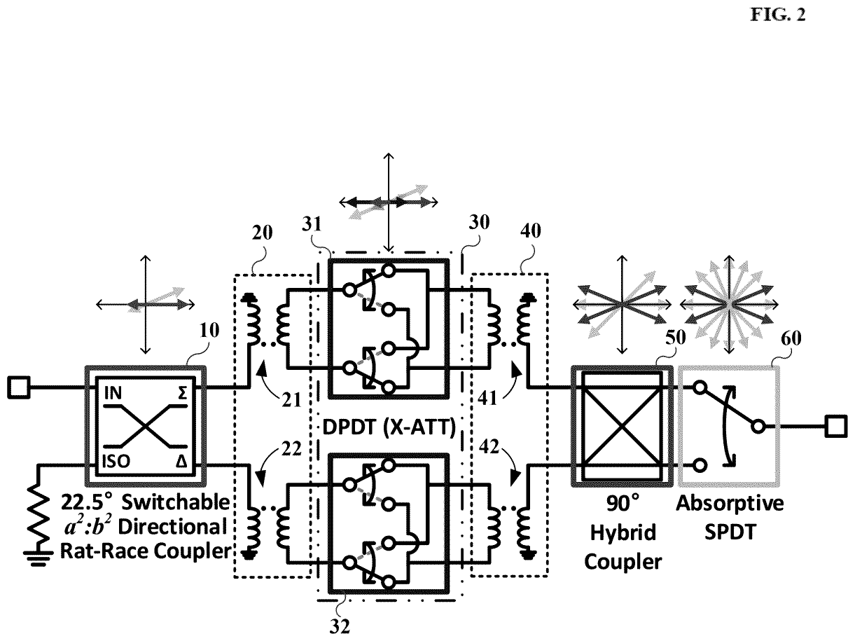

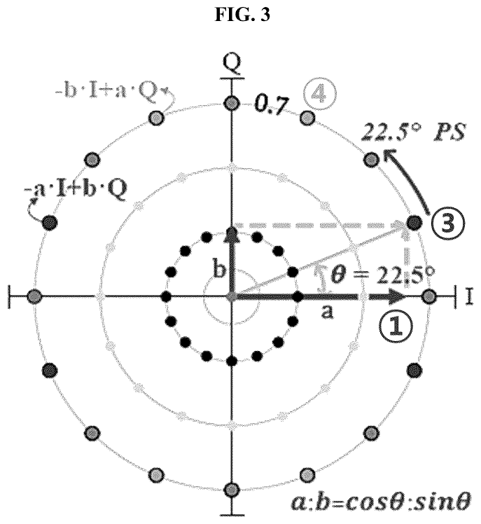

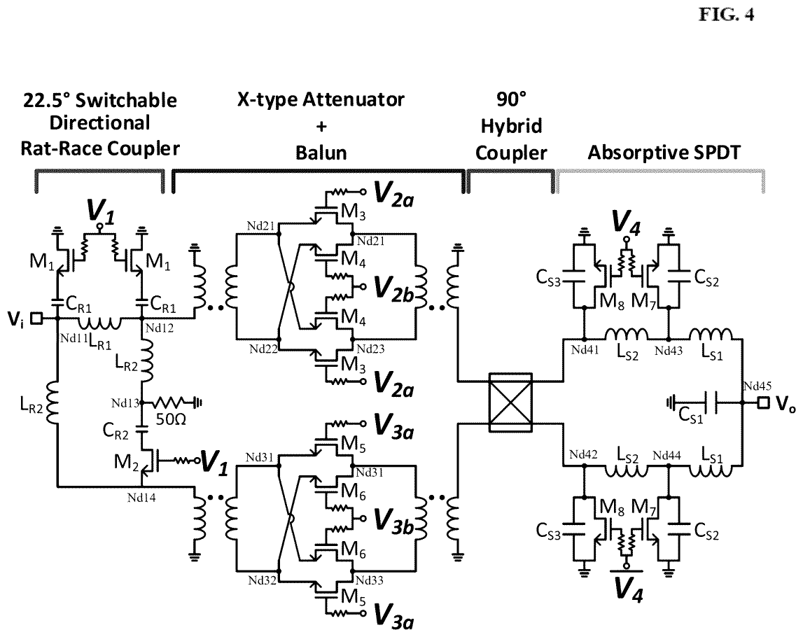

FIG. 2 illustrates a schematic configuration of a bidirectional variable gain VSPS according to an embodiment, FIG. 3 illustrates an operation of the bidirectional variable gain VSPS of the embodiment shown in FIG. 2, and FIG. 4 illustrates an example of a detailed configuration of the bidirectional variable gain VSPS of FIG. 1.

Referring to FIG. 2, a bidirectional variable gain VSPS according to an embodiment includes a Rat-Race Coupler (RRC) 10, a phase inversion switch circuit 30, a hybrid coupler 50, a phase selection switch 60, and first and second balun circuits 20 and 40.

The rat-race coupler 10 asymmetrically distributes an applied input signal to divide the input signal into two distributed signals. The rat-race coupler 10 may distribute power of the applied signal and divide the applied signal into two distributed signals having different power levels. The rat-race coupler 10 may distribute power of the input signal at a ratio of a² to b² to divide the input signal into two signals. The rat-race coupler 10 may be configured to divide the input signal into two asymmetrically power-distributed signals by differentiating an impedance (Z₀) of paths along which the input signal, divided into two signals, is transmitted.

In an embodiment, as illustrated in FIG. 4, the rat-race coupler 10 may be implemented as a switchable directional rat-race coupler (SDRRC) in which a length of a transmission path through which the input signal is transmitted is varied according to a phase selection signal (V₁), such that phases of the two asymmetrically power-distributed signals are phase-shifted.

In an embodiment, the rat-race coupler 10 may be configured to asymmetrically distribute an input signal based on a reference phase (θ). As illustrated in FIG. 4, the rat-race coupler 10 may include a plurality of inductors (L_{R1}, L_{R2}) and a plurality of capacitors (C_{R1}, C_{R2}) disposed along paths through which distributed signals are transmitted, and a plurality of switch transistors (M₁, M₂) that are turned on and off according to a phase selection signal (V₁). Here, the plurality of inductors (L_{R1}, L_{R2}) and capacitors (C_{R1}, C_{R2}) affect a transmitted signal regardless of the phase selection signal (V₁), and when the switch transistors (M₁, M₂) are turned on according to the phase selection signal (V₁), the capacitors (C_{R1}, C_{R2}) are coupled with parasitic capacitances of the turned-on switch transistors (M₁, M₂), thereby phase-shifting phases of two asymmetrically power-distributed signals.

Accordingly, the rat-race coupler 10 may output the two asymmetrically power-distributed signals while maintaining a power distribution ratio (a²:b²) and phase-shifting the phases of the two asymmetrically power-distributed signals according to the phase selection signal (V₁).

That is, the rat-race coupler 10 may be configured to asymmetrically distribute the input signal at a magnitude ratio of cos²(θ) to sin²(θ) corresponding to the reference phase (θ), and, when the phase selection signal (V₁) is activated, to phase-shift respective phases of the two asymmetrically power-distributed signals. Here, it is assumed that, when the phase selection signal (V₁) is activated, the rat-race coupler 10 phase-shifts the phases of the two asymmetrically power-distributed signals by the reference phase (θ).

Here, the reason why the rat-race coupler 10 asymmetrically distributes the input signal at a ratio corresponding to the reference phase (θ) and phase-shifts the input signal by the reference phase (θ) according to the phase selection signal (V₁) is to allow the bidirectional variable gain VSPS according to the embodiment to output the output signals having various phase states distinguished in units of the reference phase (θ). The rat-race coupler 10 may asymmetrically distribute first and second signals at a ratio of) cos²(22.5°) to sin²(22.5°), as indicated by \textcircled{1} in FIG. 3 based on the reference phase (θ=22.5°), such that a phase state of an output signal output from the VSPS becomes, as indicated by \textcircled{3} in FIG. 3, a·I+b·Q=22.5°. Further, according to the phase selection signal (V₁), phases of the two distributed signals may be phase-shifted by the reference phase (0=) 22.5°, such that the phase state of the output signal output from the VSPS becomes a·I+b·Q=45°.

Hereinafter, a case in which the rat-race coupler 10 distributes power at a ratio of) cos²(22.5°) to sin²(22.5°) corresponding to the reference phase (θ) will be assumed for description.

The first balun circuit 20 converts two distributed signals distributed by the rat-race coupler 10 into differential signals, respectively. That is, the first balun circuit 20 includes two balun transformers 21 and 22, and converts each of the first and second distributed signals, which are single-ended signals, into first and second differential signals. Here, it is assumed that, among the two first balun transformers 21 and 22, a first-first balun transformer 21 receives the first distributed signal and converts the first distributed signal into the first differential signal, and a first-second balun transformer 22 receives the second distributed signal and converts the second distributed signal into the second differential signal.

The phase inversion switch circuit 30 may be configured to receive the first and second differential signals converted by the first balun circuit 20, and to selectively pass the first and second differential signals either without phase inversion or with a 180° phase inversion in accordance with first and second switching control signals (V₂ₐ, V_{2b}) and (V₃ₐ, V_{3b}), respectively. In one embodiment, the phase inversion switch circuit 30 may include two phase inversion switches 31 and 32 and may be configured to independently perform phase inversion on the first and second differential signals, respectively.

Among the two phase inversion switches 31 and 32, the first phase inversion switch 31 receives the first differential signal from the first-first balun transformer 21, and, according to the first switching control signals (V₂ₐ, V_{2b}), passes the applied first differential signal without phase inversion or with phase inversion. Further, the second phase inversion switch 32 receives the second differential signal from the first-second balun transformer 22, and, according to the second switching control signals (V₃ₐ, V_{3b}), passes the applied second differential signal without phase inversion or with phase inversion.

Here, the two phase inversion switches 31 and 32 may be implemented as DPDT (Double-Pole Double-Throw) switches. Each of the two phase inversion switches 31 and 32 implemented as DPDT switches includes four switch transistors ((M₃, M₄), (M₅, M₆)) cross-connected between two nodes to which the first or second differential signal is applied. In the first phase inversion switch 31, among four switch transistors M₃ and M₄, two first switch transistors M₃ are turned on and off in response to first-first switching control signals (V₂ₐ), and two second switch transistors M₄ are turned on and off in response to first-second switching control signals (V_{2b}). In the second phase inversion switch 32, among four switch transistors M₅ and M₆, two first switch transistors M₅ are turned on and off in response to second-first switching control signals (V₃ₐ), and two second switch transistors M₆ are turned on and off in response to second-second switching control signals (V_{3b}).

As described above, since the phase inversion switch circuit 30 is capable of independently 180° phase-inverting each of the first and second differential signals, a phase state set to a·I+b·Q=22.5°, as indicated by \textcircled{1} in FIG. 3 by the rat-race coupler 10, may be changed into various combinations. Specifically, the phase inversion switch circuit 30 may invert only a phase of the second differential signal from a phase state (a·I+b·Q=22.5°) coupler 10, such that the phase state becomes a·I−b·Q=−22.5°, or may invert only a phase of the first differential signal, such that the phase state becomes −a· I+b·Q=157.5°. In addition, phases of both the first and second differential signals may be inverted, such that the phase state becomes −a·I−b·Q=157.5°. That is, the phase inversion switch circuit 30 may set the phase state of the output signal of the VSPS to one of phase states (±22.5°, ±157.5°) indicated by red points in FIG. 3.

In this case, each of the two phase inversion switches 31 and 32 may also operate as an attenuator configured to adjust magnitudes of the first and second differential signals according to voltage levels of the first and second switching control signals ((V₂ₐ, V_{2b}), (V₃ₐ, V_{3b})).

That is, the phase inversion switch circuit 30 not only controls whether to phase-invert each of the first and second differential signals, but also controls magnitudes thereof. When magnitudes of the first and second differential signals are adjusted, a magnitude of an output signal of the VSPS is adjusted. That is, the phase inversion switch circuit 30 may also control a gain of the VSPS.

Meanwhile, the second balun circuit 40 receives the first and second differential signals whose phases and magnitudes are adjusted by the phase inversion switch circuit 30, and obtains first and second converted signals that are single-ended signals, respectively. The second balun circuit 40 may also include two balun transformers 41 and 42, and convert the first and second differential signals into the first and second converted signals.

The hybrid coupler 50 receives the first and second converted signals converted by the second balun circuit 40, and combines the applied first and second converted signals as an I signal and a Q signal, respectively, to obtain a first phase-shifted signal. Meanwhile, the hybrid coupler 50 interchanges the first and second converted signals as a Q signal and an I signal, respectively, and combines them to obtain a second phase-shifted signal. Here, the first phase-shifted signal is a signal combined (a·I+b·Q) at a ratio set by the rat-race coupler 10, and the second phase-shifted signal is a signal combined (b·I+a·Q) by interchanging a combination ratio (a:b) to (b:a). Accordingly, the first and second phase-shifted signals have the same magnitude and have a phase difference of 45° therebetween.

Accordingly, when a combination (±a·I+b·Q) of the first and second converted signals transmitted from the second balun circuit 40 represents one of phase states of ±22.5° and ±157.5°, the hybrid coupler 50 may output the first phase-shifted signal having one of phase states of ±22.5° and ±157.5° corresponding to red points in FIG. 3, and the second phase-shifted signal having a phase difference of 90° with respect to the first phase-shifted signal and having one of phase states of +67.5° and +112.5° corresponding to green points in FIG. 3.

The phase selection switch 60 selects one of two phase-shifted signals transmitted from the hybrid coupler 50 and having a 90° phase difference therebetween, in response to a third switching control signal V₄, and outputs the selected signal as an output signal. Here, in order to prevent distortion due to reflected signals by achieving impedance matching at 50Ω at all four ports of the hybrid coupler 50, the phase selection switch 60 may be implemented as an absorptive single-pole double-throw (SPDT) switch including a plurality of inductors (L_{S1}, L_{S2}) and a plurality of capacitors (C_{S1} to C_{S3}) connected on a signal transmission path, as illustrated in FIG. 4.

Accordingly, the VSPS may output an output signal having one of eight phase states of ±22.5°, ±67.5°, ±112.5°, and ±157.5° with respect to an input signal.

However, as described above, in one embodiment, the rat-race coupler 10 may phase-shift signals power-distributed at a ratio of) cos²(22.5°) to sin²(22.5°) by a reference phase (θ) in response to the phase selection signal V₁. Accordingly, when the rat-race coupler 10 distributes power of an input signal and phase-shifts the same to obtain first and second distributed signals, the VSPS of one embodiment may output an output signal having one of eight additional phase states of 0°, +45°, +90°, +135°, and 180°, which are indicated by gray points in FIG. 3.

Therefore, the bidirectional variable gain VSPS of one embodiment may output an output signal having one of sixteen phase states of 0°, ±22.5°, ±45°, ±67.5°, ±90°, ±112.5°, ±135°, ±157.5°, and 180°, and having one of gains of 0.3, 0.5, and 0.7. Since the bidirectional variable gain VSPS combines asymmetrically power-distributed I and Q signals in various combinations using the rat-race coupler 10 without attenuation to obtain a required phase state, insertion loss may be significantly reduced. In addition, while passing through the two phase inversion switches 31 and 32 of the phase inversion switch circuit 30, the magnitudes of the first and second differential signals may be adjusted, thereby easily varying the gain. Furthermore, since points corresponding to the gain and phase states of the output signal are all located on a gain circle of an S21 polar plot, additional gain adjustment is not required, and thus additional attenuation can be prevented. In addition, since reverse operation is also possible, gain and phase can be adjusted bidirectionally, such that even a single VSPS may be provided to adjust phases in both transmission and reception of a communication device.

In the bidirectional variable gain VSPS illustrated in FIG. 4, the inductors (L_{R1}, L_{R2}, L_{S1}, L_{S2}), the capacitors (C_{R1}, C_{R2}, C_{S1}, C_{S2}), and the switch transistors (M₁ to M₈) may have inductances, capacitances, and widths according to Table 1 by way of example.

TABLE 1

| Inductor (pH) | | | Capacitor (fF) | | | | Transistor Width (um) | | | |
|---|---|---|---|---|---|---|---|---|---|---|
| L_{R1} | L_{R2} | L_{S1, 2} | C_{R1} | C_{R2} | C_{S1} | C_{S2} | M₁₋₂ | M₃₋₆ | M₇ | M₈ |
| 280 | 120 | 100 | 35 | 14 | 55 | 43 | 28 | 22 | 100 | 8 |

The above-described bidirectional variable gain VSPS may be provided in a communication device, and the phase selection signal V₁, the first and second switching control signals (V₂ₐ, V_{2b}) and (V₃ₐ, V_{3b}) for determining whether to invert phases of the first and second differential signals, and the third switching control signal V₄ for selecting one of the first and second phase-shifted signals may be applied from a controller (not shown) provided in the communication device.

The bidirectional variable gain phase shifter according to one embodiment may be utilized in various millimeter-wave band array antenna systems. For example, it may be applied to beamforming systems of 5G mobile communication base stations and terminals, vehicle radar systems, and satellite communication systems. Specifically, in an array antenna system, electronic beam steering is performed by adjusting phase differences among a plurality of antenna elements. In this case, the phase shifter of the present disclosure is connected to each antenna element to precisely control phases of transmit and receive signals, thereby enabling formation and steering of a beam in a desired direction.

In particular, in a millimeter-wave band, high-gain beamforming is essential to overcome high path loss, and the phase shifter of the present disclosure is suitable for effective beamforming implementation since bidirectional operation and precise phase control are possible. In addition, since it is usable in both transmit and receive channels, system size and complexity can be reduced.

In the illustrated embodiment, respective configurations may have different functions and capabilities in addition to those described above, and may include additional configurations in addition to those described above. In addition, in an embodiment, each configuration may be implemented using one or more physically separated devices, or may be implemented by one or more processors or a combination of one or more processors and software, and may not be clearly distinguished in specific operations unlike the illustrated example.

In addition, the bidirectional variable gain VSPS illustrated in FIG. 2 may be implemented in a logic circuit by hardware, firm ware, software, or a combination thereof or may be implemented using a general purpose or special purpose computer. The apparatus may be implemented using hardwired device, field programmable gate array (FPGA) or application specific integrated circuit (ASIC). Further, the apparatus may be implemented by a system on chip (SoC) including one or more processors and a controller.

In addition, the bidirectional variable gain phase shifter may be mounted in a computing device or server provided with a hardware element as a software, a hardware, or a combination thereof. The computing device or server may refer to various devices including all or some of a communication device for communicating with various devices and wired/wireless communication networks such as a communication modem, a memory which stores data for executing programs, and a microprocessor which executes programs to perform operations and commands.

The present disclosure has been described in detail through a representative embodiment, but those of ordinary skill in the art to which the art pertains will appreciate that various modifications and other equivalent embodiments are possible. Therefore, the true technical protection scope of the present disclosure should be defined by the claims.

What is claimed is:

1. A bidirectional variable gain phase shifter comprising:
a rat-race coupler configured to distribute an input signal at a predetermined ratio and divide the input signal into first and second distributed signals;
a phase inversion switch circuit configured to selectively invert phases of the respective first and second distributed signals;
a hybrid coupler configured to receive two signals output from the phase inversion switch circuit, to phase-shift and combine the received signals, and to obtain first and second phase-shifted signals; and
a phase selection switch configured to select one of the first and second phase-shifted signals and output the selected signal as an output signal.

2. The bidirectional variable gain phase shifter according to claim 1,
wherein the rat-race coupler distributes the input signal into the first and second distributed signals at a ratio of cos²(θ) to sin²(θ) according to a predetermined reference phase (θ).

3. The bidirectional variable gain phase shifter according to claim 2,
wherein the rat-race coupler is implemented as a switchable directional rat-race coupler configured to phase-shift and output the first and second distributed signals in response to a phase selection signal.

4. The bidirectional variable gain phase shifter according to claim 3,
wherein the rat-race coupler phase-shifts the first and second distributed signals by varying an electrical length of a path through which the input signal is transmitted, by means of at least one switch transistor to which the phase selection signal is applied as a gate signal.

5. The bidirectional variable gain phase shifter according to claim 3,
wherein the reference phase is set to π/8.

6. The bidirectional variable gain phase shifter according to claim 1,
wherein the phase inversion switch circuit includes:
a first phase inversion switch configured to receive the first distributed signal and to selectively pass the first distributed signal without phase inversion or with phase inversion in response to a first switching control signal, and
a second phase inversion switch configured to receive the second distributed signal and to selectively pass the second distributed signal without phase inversion or with phase inversion in response to a second switching control signal.

7. The bidirectional variable gain phase shifter according to claim 6,
wherein the first phase inversion switch adjusts a magnitude of the first distributed signal according to a voltage level of the first switching control signal, and the second phase inversion switch adjusts a magnitude of the second distributed signal according to a voltage level of the second switching control signal.

8. The bidirectional variable gain phase shifter according to claim 6,
wherein the first phase inversion switch is implemented as a DPDT (Double-Pole Double-Throw) switch.

9. The bidirectional variable gain phase shifter according to claim 6,
wherein the hybrid coupler:
combines two signals output from the phase inversion switch circuit as an I signal and a Q signal, respectively, to obtain the first phase-shifted signal, and interchangeably combines the two signals as a Q signal and an I signal, respectively, to obtain the second phase-shifted signal.

10. The bidirectional variable gain phase shifter according to claim 6,
wherein the phase selection switch selects one of the first and second phase-shifted signals as the output signal in response to a third switching control signal.

11. The bidirectional variable gain phase shifter according to claim 6,
wherein the phase selection switch is implemented as an absorptive SPDT (Single-Pole Double-Throw) switch so as to achieve impedance matching with the hybrid coupler.

12. The bidirectional variable gain phase shifter according to claim 1,
wherein the bidirectional variable gain phase shifter further comprises
a first balun circuit configured to convert the first and second distributed signals into differential signals, respectively, and
a second balun circuit configured to convert two signals output as differential signals from the phase inversion switch circuit into single-ended signals, respectively.

13. The bidirectional variable gain phase shifter according to claim 1,
wherein the bidirectional variable gain phase shifter
is provided in a communication device, and,
under control of a controller included in the communication device, is configured to set a power distribution ratio of the input signal, to determine whether to invert phases of the first and second distributed signals, and to select one of the first and second phase-shifted signals.
